(19) United States
(12) Patent Application Publication
(10) Pub. No.: US 2015/0181726 A1
(43) Pub. Date: Jun. 25, 2015

(54) MOUNTING APPARATUS AND SCREW ASSEMBLY FOR THE SAME

(71) Applicants: HON HAI PRECISION INDUSTRY CO., LTD., New Taipei (TW); HONG FU JIN PRECISION INDUSTRY (Shenzhen) CO., LTD, Shenzhen (CN)

(72) Inventors: HAN-YU LI, New Taipei (TW); CHENG-HE LI, Shenzhen (CN)

(73) Assignees: HON HAI PRECISION INDUSTRY CO., LTD., New Taipei (TW); HONG FU JIN PRECISION INDUSTRY (Shenzhen) CO., LTD, Shenzhen (CN)

(21) Appl. No.: 14/195,404

(22) Filed: Mar. 3, 2014

(30) Foreign Application Priority Data
Dec. 24, 2013 (CN) 2013107203178

(51) Int. Cl. H05K 5/00; F16B 33/00

(52) U.S. Cl. CPC H05K 5/0008; F16B 33/00

(57) ABSTRACT

A screw assembly includes a bolt, a stopping member, and a nut fitted about the bolt. The bolt includes a screw. A side of the screw forms a stopping surface extending along a lengthwise direction of the screw. The stopping member is fitted about the screw. A tab protrudes out from an outer side of the stopping member to abut the stopping surface of the screw to prevent the screw from rotating.

### FIELD

The present disclosure relates to mounting apparatuses, and more particularly to a mounting apparatus with a screw assembly.

### BACKGROUND

An electronic apparatus, such as a server cabinet, usually includes a cabinet and a mounting apparatus for positioning the cabinet to a supporting surface. The installation of the mounting apparatus to the supporting surface typically involves the use of screws and nuts to attach the mounting apparatus. However, the screws with the corresponding nuts tend to rotate together.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a mounting apparatus for mounting a cabinet, wherein the mounting apparatus includes a plurality of screw assemblies.

FIG. 2 is an enlarged, exploded, isometric view of one of the screw assemblies of FIG. 1.

FIGS. 3, 4 and 5 are isometric, cutaway views showing the process of assembling the mounting apparatus of FIG. 1.

FIG. 6 is an assembled, isometric view of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

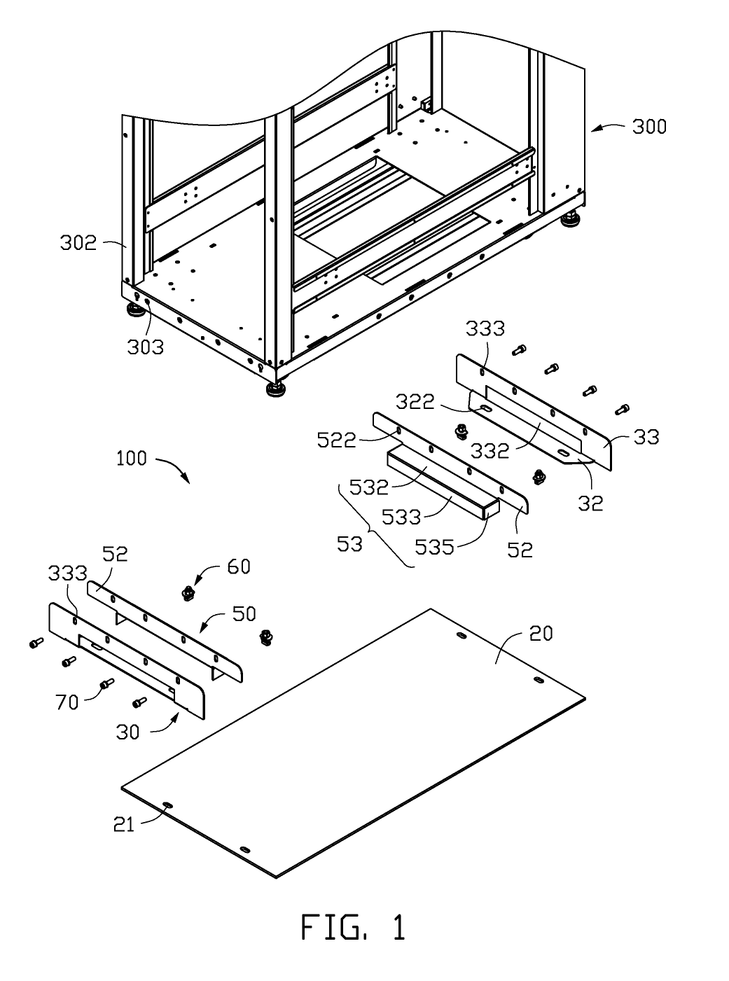

FIG. 1 shows an exemplary embodiment of a mounting apparatus 100 for mounting an electronic apparatus 300. The electronic apparatus 300 comprises a cabinet 302. Two opposite end walls of a bottom of the cabinet 302 can define a plurality of mounting holes 303. The mounting apparatus 100 comprises a supporting plate 20, two connecting members 30, two shielding members 50, four screw assemblies 60, and a plurality of fasteners 70.

Two opposite ends of the supporting plate 20 respectively can define two slots 21 extending along a direction perpendicular to a lengthwise direction of the supporting plate 20.

Each connecting member 30 can be substantially L-shaped, and comprises a rectangular positioning plate 32 and a connecting plate 33 perpendicularly extending up from a side of the positioning plate 32. Two opposite ends of the positioning plate 32 can define two bar-shaped positioning holes 322 extending along a lengthwise direction of the positioning plate 32. A middle of a bottom side of the connecting plate 33 can define a through slot 332 extending along a lengthwise direction of the connecting plate 33. A top side of the connecting plate 33 can define a plurality of through holes 333 arrayed along the lengthwise direction of the connecting plate 33.

Each shielding member 50 comprises a rectangular connecting piece 52 and a shell 53 protruding out from a bottom side of the connecting piece 52. The shell 53 comprises a top plate 532 extending perpendicularly out from the connecting piece 52, a side plate 533 extending perpendicularly down from a distal side of the top plate 532, and two end plates 535 extending perpendicularly down from two opposite ends of the top plate 532 and connected with the side plate 533. A top of the connecting piece 52 can define a plurality of installation holes 522 arrayed along a lengthwise direction of the connecting piece 52.

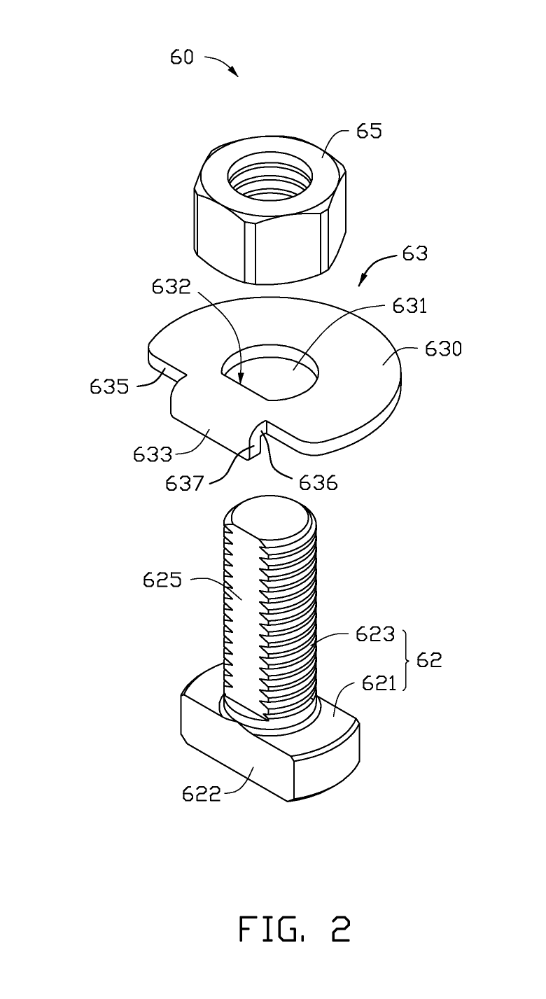

FIG. 2 shows one screw assembly 60, the screw assembly 60 comprises a bolt 62, a stopping member 63, and a nut 65 fitted about the bolt 62. The bolt 62 comprises a bar-shaped screw cap 621 and a screw 623 perpendicularly extending up from a middle of the screw cap 621. A side of the screw 623 forms a stopping surface 625 extending along a lengthwise direction of the screw cap 621. The screw cap 621 comprises a side surface 622 parallel to the stopping surface 625.

The stopping member 63 comprises a D-shaped positioning piece 630 and a substantially L-shaped tab 633 extending down from the positioning piece 630. A middle of the positioning piece 630 can define a substantially D-shaped locating hole 631. The locating hole 631 comprises a positioning surface 632 parallel to a straight flange 635 of the positioning piece 630. The tab 633 comprises an extending portion 636 extending from a middle of the straight flange 635 and a latching portion 637 perpendicularly extending down from a distal end of the extending portion 636.

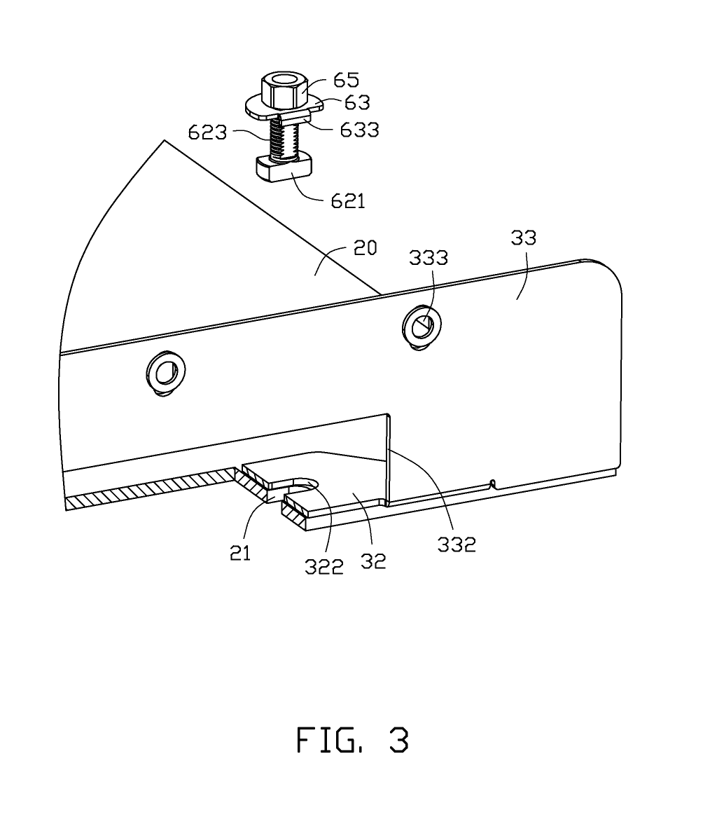

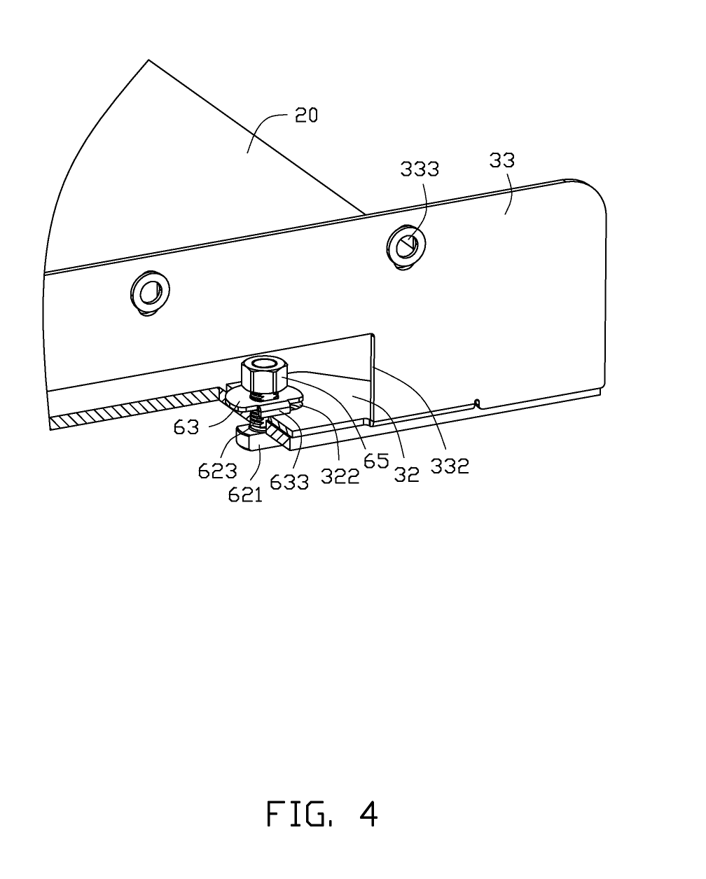

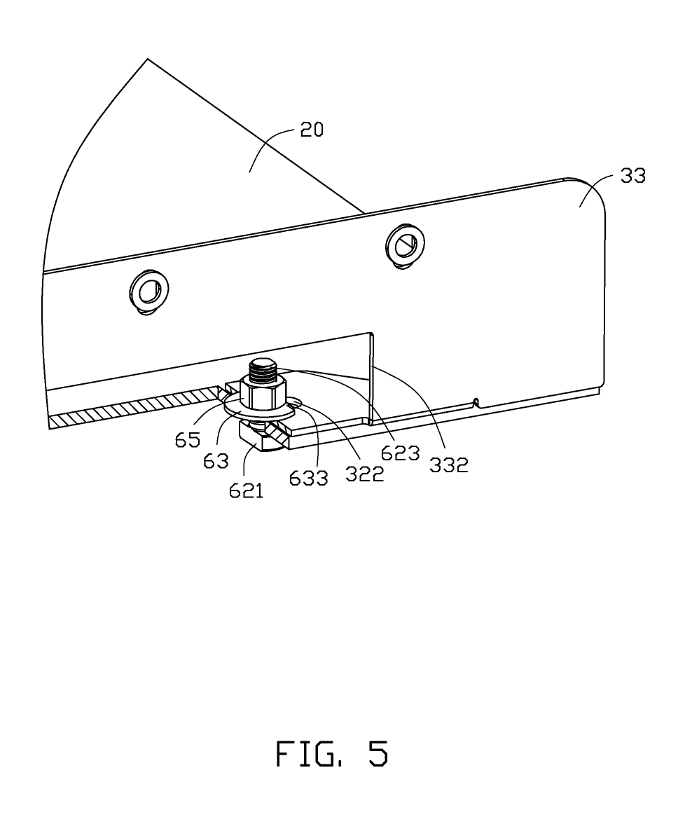

FIGS. 3-5 show that in assembling the mounting apparatus 100, screws 623 are inserted in the locating holes 631 of the stopping members 63. The stopping surface 625 of each screw 623 engages with the positioning surface 632 of the corresponding stopping member 63, and the tab 633 is located adjacent to the corresponding screw cap 621. Tops of the screws 623 can be rotated in the nuts 65. The positioning plate 32 of the connecting members 30 can be supported on the supporting plate 20, and the positioning holes 322 align with the corresponding slots 21. The screw caps 621 of the screw assemblies 60 can be extended through the positioning holes 322 and the corresponding slots 21, until the screw caps 621 are exposed from a bottom surface of the supporting plate 20. The stopping members 63 can be supported on the positioning plates 32. The screw assembles 60 can be rotated 90 degrees, the screw caps 621 can engage with the bottom surface of the supporting plate 20, and the tabs 633 can be inserted in the corresponding positioning holes 322. The nuts 65 can be tightened for fastening the connecting members 30 on the supporting plate 20. The shells 53 can be supported on the positioning plates 32, the connecting pieces 52 can engage with the corresponding connecting plates 33, and the installing holes 522 of each shell 53 can align with the through holes 333 of the corresponding connecting plate 33. The shell 53 shields the screw assemblies 60.

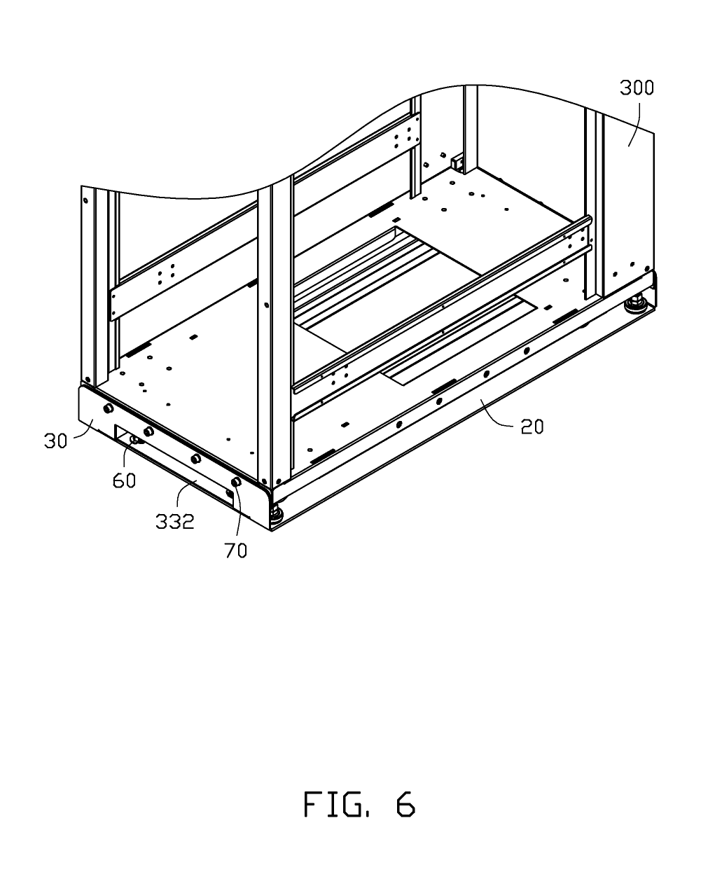

FIG. 6 shows that in use, the cabinet 302 can be supported on the supporting plate 20 and can be located between the shielding members 50, to allow the end walls of the cabinet 302 to engage with the connecting pieces 52. The mounting holes 303 can be aligned with the installing holes 522. The fasteners 70 can extend through the through holes 333 and the installation holes 522, to be mounted in the corresponding mounting holes 303. Therefore, the electronic apparatus 300 can be mounted on the supporting plate 20.

When disengaging the electronic apparatus 300 from the supporting plate 20, the nuts 65 can be rotated to be released through the through slots 332. The stopping members 63 can be moved away from the supporting plate 20, until the tabs 633 are disengaged from the position holes 322. The screw assemblies 60 can be rotated through the through slot 332, until the screw caps 621 align with the corresponding slots 21. The screw assemblies 60 can be disengaged from the supporting plate 20.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A screw assembly, comprising:
a bolt comprising a screw, wherein a side of the screw forms a stopping surface extending along a lengthwise direction of the screw;
a stopping member fitted about the screw; a tab protruding out from an outer side of the stopping member to abut the stopping surface of the screw; and
a nut fitted about the bolt.

2. The screw assembly of claim 1, wherein the bolt further comprises a bar-shaped screw cap perpendicularly located on an end of the screw.

3. The screw assembly of claim 1, wherein the tab further comprises an extending portion extending from the stopping member and a latching portion extending down from a distal end of the extending portion.

4. The screw assembly of claim 1, wherein the stopping member further comprises: a position piece, the tab being located at an outer side of the position piece; a middle of the position piece defines a D-shaped locating hole, the screw extended through the locating hole; and the locating hole comprises a position surface parallel to a straight flange of the positioning piece, the position surface of the locating hole is engaged with the stopping surface of the screw.

5. A mounting apparatus for an electronic apparatus comprising:
a supporting plate for supporting the electronic apparatus and defining a plurality of slots;
a pair of connecting members, each comprising a positioning plate supported on the supporting plate and a connecting plate extending up from a side of the positioning plate, wherein the positioning plates define a plurality of position holes aligning with the slots of the supporting plate;
a plurality of screw assemblies, each comprising a bolt extended through the position holes and the corresponding slots, to engage with a bottom surface of the supporting plate, a stopping member, and a nut fitted about the bolt; and
a plurality of fasteners;
wherein each bolt comprises a screw, a side of each screw forms a stopping surface extending along a lengthwise direction of the screw, the stopping members are fitted about the screws, each stopping member comprises a tab protruding out from the stopping member, each screw assemblies is rotated, to allow the tab to align with the corresponding position hole, when the nuts are tightened, the tabs are latched in the position holes of the connecting members, and the fasteners extend through the connecting plates, and engage to the electronic apparatus.

6. The mounting apparatus of claim 5, wherein the connecting plates define a plurality of through holes, and the fasteners extend through the through holes of the connecting plates, and engage to the electronic apparatus.

7. The mounting apparatus of claim 5, wherein the position holes are bar-shaped, each bolt further comprises a bar-shaped screw cap perpendicularly located on an end of the corresponding screw, the screw caps extend through the position holes and the corresponding slots, to expose the bottom surface of the supporting plate, the screw assemblies are rotated, until the screw caps engage with the bottom surface of the supporting plate and the tabs are inserted in the corresponding position holes.

8. The mounting apparatus of claim 5, wherein each tab further comprises an extending portion extending out from the stopping member and a latching portion extending down from a distal end of the extending portion, and the latching portion is latched in the corresponding position hole.

9. The mounting apparatus of claim 5, wherein each stopping member further comprises a position piece supported on the corresponding positioning plate, the tab is located at an outer side of the position piece, a middle of the position piece defines a locating hole, the screw is extended through the locating hole, and the locating hole comprises a position surface engaged with the stopping surface of the screw.

10. The mounting apparatus of claim 5, further comprising a pair of shielding members, wherein each shielding member comprises a connecting piece mounted between the corresponding connecting plate and the electronic apparatus, and a shell protruding out from the connecting piece to shield the corresponding screw assemblies.

11. The mounting apparatus of claim 5, wherein a middle of each connecting plate defines a through slot adjacent to the position holes, and the nuts are disengaged from the connecting members through the through slot.

12. An electronic device, comprising:
a supporting plate defining a plurality of slots;
a cabinet supported on the supporting plate;
a pair of connecting members, each comprising a positioning plate supported on the supporting plate and a connecting plate extending up from a side of the positioning plate, wherein the positioning plates define a plurality of position holes aligning with the slots of the supporting plate;
a plurality of screw assemblies, each comprising a bolt extending through the position holes and the corresponding slots engaging with a bottom surface of the supporting plate, a stopping member, and a nut fitted about the bolt; and
a plurality of fasteners;
wherein each bolt comprises a screw, a side of each screw forms a stopping surface extending along a lengthwise direction of the screw, the stopping members are fitted about the screws, each stopping member comprises a tab protruding out from the stopping member, the tabs are latched in the position holes of the connecting members, the cabinet is located between the connecting members, the fasteners extend through the connecting plates, and engage to the cabinet.

13. The electronic device of claim 12, wherein the connecting plates define a plurality of through holes, the cabinet defines a plurality of mounting holes aligning with the through hole, and the fasteners extend through the through holes of the connecting plates, and engage in the mounting holes of the cabinet.
